(19) United States
(12) Patent Application Publication
(10) Pub. No.: US 2024/0087898 A1
(43) Pub. Date: Mar. 14, 2024

(54) SEMICONDUCTOR DEVICE AND METHOD OF MANUFACTURING THE SAME

(71) Applicants: Kabushiki Kaisha Toshiba, Tokyo (JP); Toshiba Electronic Devices & Storage Corporation, Tokyo (JP)

(72) Inventor: Seiya SAKAKURA, Hakusan Ishikawa (JP)

(21) Appl. No.: 18/117,498

(22) Filed: Mar. 6, 2023

(30) Foreign Application Priority Data
Sep. 12, 2022 (JP) 2022-144723

(51) Int. Cl. H01L 21/22; H01L 29/32; H01L 29/739

(52) U.S. Cl. CPC H01L 21/221; H01L 29/32; H01L 29/7397

(57) ABSTRACT

Provided is a semiconductor device including: a first semiconductor layer of a first conductivity type, and the first semiconductor layer including first conductivity type impurities; a second semiconductor layer of the first conductivity type provided on the first semiconductor layer, and the second semiconductor layer including lower first conductivity type impurities than the first semiconductor layer; and a third semiconductor layer provided in the first semiconductor layer, and the third semiconductor layer including a hydrogen concentration of 5×10¹⁷ atoms/cm³ or more.

### CROSS-REFERENCE TO RELATED APPLICATION

This application is based upon and claims the benefit of priority from Japanese Patent Application No. 2022-144723, filed on Sep. 12, 2022, the entire contents of which are incorporated herein by reference.

### FIELD

Embodiments described herein relate generally to semiconductor device.

### BACKGROUND

Semiconductor devices such as MOSFET (Metal Oxide Semiconductor Field Effect Transistor) and IGBT (Insulated Gate Bipolar Transistor) are used for power converters and the like.

### BRIEF DESCRIPTION OF THE DRAWINGS

FIG. 1 is a schematic cross-sectional view of a semiconductor device according to a first embodiment;

FIG. 2 is a schematic cross-sectional view of a semiconductor device according to another aspect of the first embodiment;

FIG. 3 is a graph showing impurity concentration in the semiconductor device of the first embodiment;

FIG. 4 is a graph showing carrier concentration in the semiconductor device of the first embodiment;

FIG. 5 is a graph showing hydrogen concentration and n-type carrier concentration before and after the hydrogen plasma treatment in the semiconductor device of the first embodiment;

FIG. 6 is DLTS spectrum waveform before and after hydrogen plasma treatment in the semiconductor device of the first embodiment;

FIG. 7 is flow chart showing a process for manufacturing the semiconductor device of the first embodiment;

FIG. 8A-B are diagrams schematically showing the hydrogen concentration in depth direction in the semiconductor device of the first embodiment; and

FIG. 9 is a schematic cross-sectional view of a semiconductor device according to a second embodiment.

### DETAILED DESCRIPTION

Hereinafter, embodiments of the present disclosure will be described with reference to the drawings. Note that in the following description, the same members and the like are denoted by the same reference numerals, and description of members and the like once described is appropriately omitted.

In this specification, in order to illustrate the positional relationship of parts and the like, the upward direction of the drawings may be referred to as “upper”, and the downward direction of the drawings may be referred to as “lower”. Here, the terms “up” and “down” do not necessarily indicate a relationship with the direction of gravity.

Hereinafter, a case where a first conductivity type is n-type and a second conductivity type is p-type will be exemplified.

In the following description, notations of n⁺, n, n⁻, p⁺, p, and p⁻ indicate a relative level of an impurity concentration of each of the conductivity types. That is, n⁺ indicates that an impurity concentration of n-type is relatively higher than n, and n⁻ indicates that the impurity concentration of n-type is relatively lower than n. p⁺ indicates that an impurity concentration of p-type is relatively higher than p, and p⁻ indicates that the impurity concentration of p-type is relatively lower than p. Note that n⁺ type and n⁻ type may be simply referred to as n type, and p⁺ type and p⁻ type may be simply referred to as p type.

### First Embodiment

The semiconductor device of the present embodiment includes a first semiconductor layer of a first conductivity type, and the first semiconductor layer including first conductivity type impurities; a second semiconductor layer of the first conductivity type provided on the first semiconductor layer, and the second semiconductor layer including lower first conductivity type impurities than the first semiconductor layer; and a third semiconductor layer provided in the first semiconductor layer, and the third semiconductor layer including a hydrogen concentration of 5×10¹⁷ atoms/cm³ or more.

The semiconductor device of the present embodiment further includes: a first semiconductor region of a second conductivity type provided on the second semiconductor layer; a second semiconductor region of the first conductivity type provided on the first semiconductor region; a first electrode provided in a trench, the trench reaching the second semiconductor layer from above the second semiconductor region, and the first electrode facing the first semiconductor region via a first insulating film; a second insulating film provided on the first electrode; a second electrode provided on the second semiconductor region and the second insulating film; a fourth semiconductor layer provided below the first semiconductor layer; and a third electrode provided below the fourth semiconductor layer, and the third electrode being electrically connected to the fourth semiconductor layer.

Alternatively, the semiconductor device of the present embodiment further includes: a first semiconductor region of a second conductivity type provided on the second semiconductor layer; a second semiconductor region of the first conductivity type provided in the first semiconductor region; a first electrode provided above the first semiconductor region; a first insulating film provided between the first semiconductor region and the first electrode; a second insulating film provided on the first electrode; a second electrode provided on the second semiconductor region and the second insulating film; a fourth semiconductor layer provided below the first semiconductor layer; and a third electrode provided below the fourth semiconductor layer, and the third electrode being electrically connected to the fourth semiconductor layer.

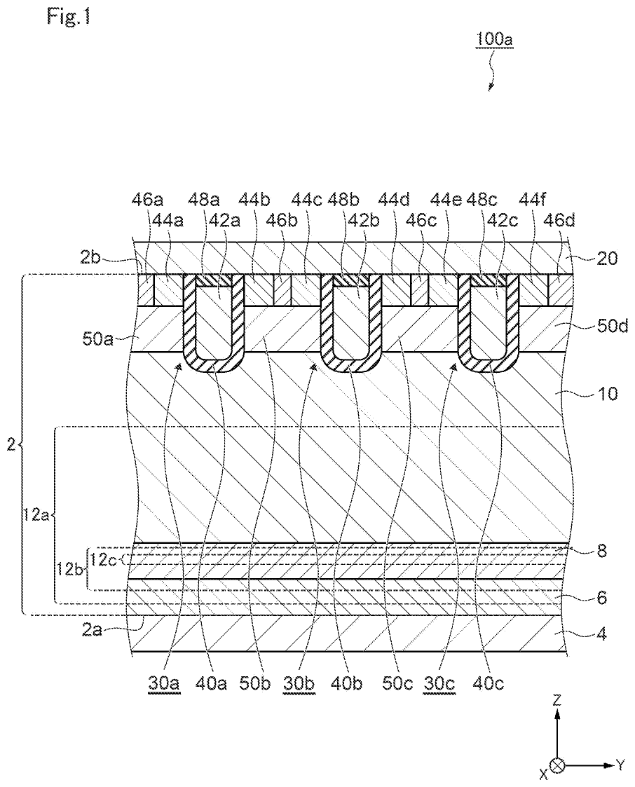

FIG. 1 is the schematic cross-sectional view of a semiconductor device 100a of the present embodiment. The semiconductor device 100a is a vertical trench type IGBT.

The semiconductor device 100a includes a semiconductor substrate 2, a collector electrode 4, a collector layer 6, an emitter electrode 20, a trench 30, a gate insulating film 40, a gate electrode 42, an emitter region 44, a contact region 46, an interlayer insulating film 48, and a base region 50. The semiconductor substrate 2 includes a first buffer layer 8, a drift layer 10, a second buffer layer 12.

The first buffer layer 8 is an example of a first semiconductor layer. The drift layer 10 is an example of a second semiconductor layer. The second buffer layer 12 is an example of a third semiconductor layer. The base region 50 is an example of a first semiconductor region. The emitter region 44 is an example of a second semiconductor region. The gate insulating film 40 is an example of a first insulating film. The gate electrode 42 is an example of a first electrode. The interlayer insulating film 48 is an example of the second insulating film. The emitter electrode 20 is an example of a second electrode. The collector layer 6 is an example of a fourth semiconductor layer. The collector electrode 4 is an example of a third electrode.

The semiconductor substrate 2 is, for example, a silicon (Si) substrate. However, the semiconductor substrate 2 may be a substrate including other semiconductor materials, such as a silicon carbide (SiC) substrate, a gallium nitride (GaN) substrate, or a gallium arsenide (GaAs) substrate. The semiconductor substrate 2 includes a first surface 2a and a second surface 2b opposite to the first surface 2a and facing the first surface 2a.

Here, when the semiconductor substrate 2 is the Si substrate, for example, arsenic (As), phosphorus (P), or antimony (Sb) can be preferably used as the n-type impurity. When the semiconductor substrate 2 is the Si substrate, for example, boron (B) can be used as the p-type impurity. In this specification, hydrogen (H) is not included in “n-type impurity” or “p-type impurity”.

Here, an X-direction, a Y-direction that intersects perpendicularly with the X-direction, and a Z-direction that intersects perpendicularly with the X-direction and the Y-direction are defined. The first surface 2a and the second surface 2b are planes parallel to XY plane. The “depth direction” of the semiconductor device 100a described later is a direction parallel to the Z-direction. FIG. 1 is a schematic cross-sectional view of the semiconductor device 100a in YZ plane.

The first buffer layer 8 is provided in the semiconductor substrate 2. The first buffer layer 8 is provided, for example, parallel to the XY plane. For example, the first buffer layer 8 is provided to suppress a depletion layer from extending when the IGBT is switched. The first buffer layer 8 includes, for example, an n⁺-type semiconductor material. The first buffer layer 8 includes n-type impurities, for example, 1×10¹⁴ atoms/cm³ or more and 1×10¹⁷ atoms/cm³ or less. The first buffer layer 8 includes hydrogen, for example, 1×10¹⁴ atoms/cm³ or more and 5×10¹⁷ atoms/cm³ or less.

The drift layer 10 is provided in the semiconductor substrate 2. The drift layer 10 is provided, for example, on the first buffer layer 8 and parallel to XY plane. The drift layer 10 includes, for example, an n⁻-type semiconductor material. The drift layer 10 includes n-type impurities, for example, 1×10¹² atoms/cm³ or more and 1×10¹⁵ atoms/cm³ or less.

The collector layer 6 is provided in the semiconductor substrate 2. The collector layer 6 is provided, for example, below the first buffer layer 8 and parallel to XY plane. The collector layer 6 includes, for example, a p⁺-type semiconductor material. The collector layer 6 includes p-type impurities, for example, 1×10¹⁶ atoms/cm³ or more and 1×10¹⁹ atoms/cm³ or less.

The collector electrode 4 is provided below the first surface 2a of the semiconductor substrate 2. The collector electrode 4 is provided below the collector layer 6. The collector electrode 4 is electrically connected to the collector layer 6.

The second buffer layer 12 is a region in which the hydrogen (H) concentration is 5×10¹⁷ atoms/cm³ or more. As will be described later, the second buffer layer 12 is formed by proton irradiation on the first surface 2a, subsequent hydrogen plasma treatment on the first surface 2a, and subsequent annealing of the semiconductor substrate 2. The second buffer layer 12 is provided, for example, to suppress the oscillation of V_{ce} (emitter-collector voltage) during switching of the IGBT.

The position at which the second buffer layer 12 is provided depends on the above-described process of proton irradiation on the first surface 2a, subsequent hydrogen plasma treatment on the first surface 2a, and subsequent annealing of the semiconductor substrate 2. For example, the second buffer layer 12 may be provided in the first buffer layer 8 as illustrated as the second buffer layer 12c in FIG. 1. In addition, the second buffer layer 12 may be provided over the collector layer 6 and the first buffer layer 8 as illustrated as the second buffer layer 12b in FIG. 1. In addition, the second buffer layer 12 may be provided over the collector layer 6, the first buffer layer 8, and the drift layer 10 as illustrated as the second buffer layer 12a in FIG. 1. In addition, for example, the second buffer layer 12 may be provided in the collector layer 6. In addition, for example, the second buffer layer 12 may be provided in the drift layer 10. In addition, for example, the second buffer layer 12 may be provided over the first buffer layer 8 and the drift layer 10. When the second buffer layer 12 is provided in the first buffer layer 8, the second buffer layer 12 is provided above (provided on) the collector layer 6.

The base region 50 is provided in the semiconductor substrate 2. The base region 50 is provided on the drift layer 10. The base region 50 includes, for example, a p-type semiconductor material. The base region 50 includes p-type impurities, for example, 1×10¹⁶ atoms/cm³ or more and 1×10¹⁸ atoms/cm³ or less. FIG. 1 shows the base region 50a, the base region 50b, the base region 50c and the base region 50d.

The emitter region 44 is provided in the semiconductor substrate 2. The emitter region 44 is provided on the base region 50. The emitter region 44 includes, for example, a n⁺-type semiconductor material. The emitter region 44 includes n-type impurities, for example, 1×10¹⁸ atoms/cm³ or more and 1×10²¹ atoms/cm³ or less. In FIG. 1, the emitter region 44a, the emitter region 44b, the emitter region 44c, the emitter region 44d, the emitter region 44e, and the emitter region 44f are illustrated.

The contact region 46 is provided in the semiconductor substrate 2. The contact region 46 is provided on the base region 50. The contact region 46 includes, for example, a p⁺-type semiconductor material. The contact region 46 includes p-type impurities, for example, 1×10¹⁸ atoms/cm³ or more and 1×10²¹ atoms/cm³ or less. In FIG. 1, the contact region 46a, the contact region 46b, the contact region 46c, and the contact region 46d are provided. The contact region 46a is provided in contact with the emitter region 44a. The contact region 46b is provided between the emitter region 44b and the emitter region 44c. The contact region 46c is provided between the emitter region 44d and the emitter region 44e. The contact region 46d is provided in contact with the emitter region 44f.

The gate electrode 42 is provided in the trench 30 which reaches the drift layer 10 from above the emitter region 44, and the gate electrode 42 is provided to face the base region 50 via the gate insulating film 40. In FIG. 1, the gate electrode 42a, the gate electrode 42b, and the gate electrode 42c are illustrated. In FIG. 1, the trench 30a, the trench 30b, and the trench 30c are illustrated. In FIG. 1, the gate insulating film 40a, the gate insulating film 40b, and the gate insulating film 40c are illustrated. The gate electrode 42a is provided in the trench 30a so as to face the base region 50a and the base region 50b via the gate insulating film 40a. The gate electrode 42b is provided in the trench 30b so as to face the base region 50b and the base region 50c via the gate insulating film 40b. The gate electrode 42c is provided in the trench 30c so as to face the base region 50c and the base region 50d via the gate insulating film 40c.

The emitter electrode 20 is provided on the emitter region 44 and the contact region 46.

The interlayer insulating film 48 is provided between the gate electrode 42 and the emitter electrode 20. The interlayer insulating film 48 insulates the gate electrode 42 and the emitter electrode 20 from each other. In FIG. 1, the interlayer insulating film 48a, the interlayer insulating film 48b, and the interlayer insulating film 48c are illustrated. The interlayer insulating film 48a is provided between the gate electrode 42a and the emitter electrode 20. The interlayer insulating film 48b is provided between the gate electrode 42b and the emitter electrode 20. The interlayer insulating film 48c is provided between the gate electrode 42c and the emitter electrode 20.

The gate insulating film 40 and the interlayer insulating film 48 include an insulator such as, for example, silicon oxide.

The collector electrode 4 and the emitter electrode 20 include a conductive material such as Al (aluminium).

The gate electrode 42 includes a conductive material such as, for example, a conductive polysilicon containing impurities.

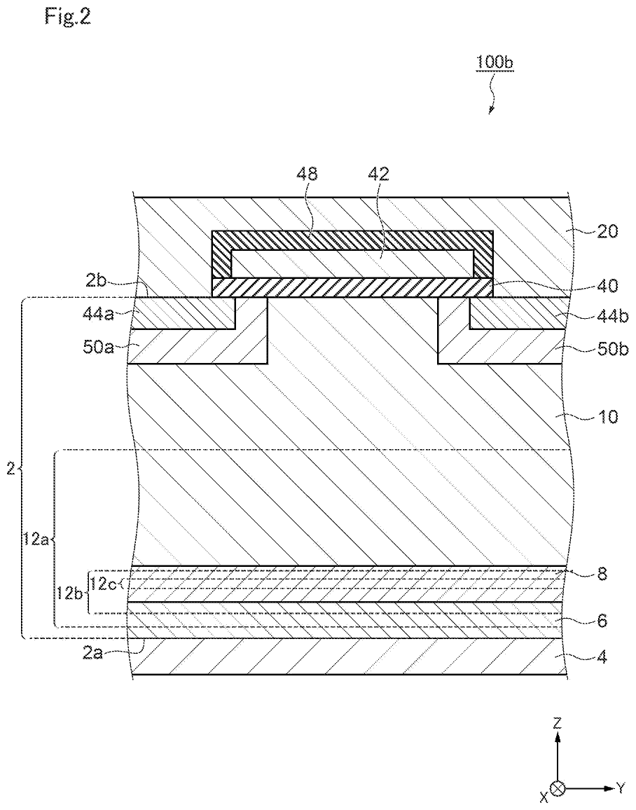

FIG. 2 is the schematic cross-sectional view of a semiconductor device 100b according to another aspect of the present embodiment. The semiconductor device 100b is a vertical planar IGBT.

In FIG. 2, the base region 50a and the base region 50b are illustrated.

The emitter region 44 is provided in the base region 50. In FIG. 2, the emitter region 44a and the emitter region 44b are illustrated. The emitter region 44a is provided in the base region 50a. The emitter region 44b is provided in the base region 50b.

The gate electrode 42 is provided above the base region 50.

The gate insulating film 40 is provided between the gate electrode 42 and the base region 50.

The emitter electrode 20 is provided on the emitter region 44 and the gate electrode 42. The emitter electrode 20 is electrically connected to the emitter region 44.

The interlayer insulating film 48 is provided between the gate electrode 42 and the emitter electrode 20.

The semiconductor device 100a shown in FIG. 1 and the semiconductor device 100b shown in FIG. 2 are both preferable for the semiconductor device 100 of the present embodiment.

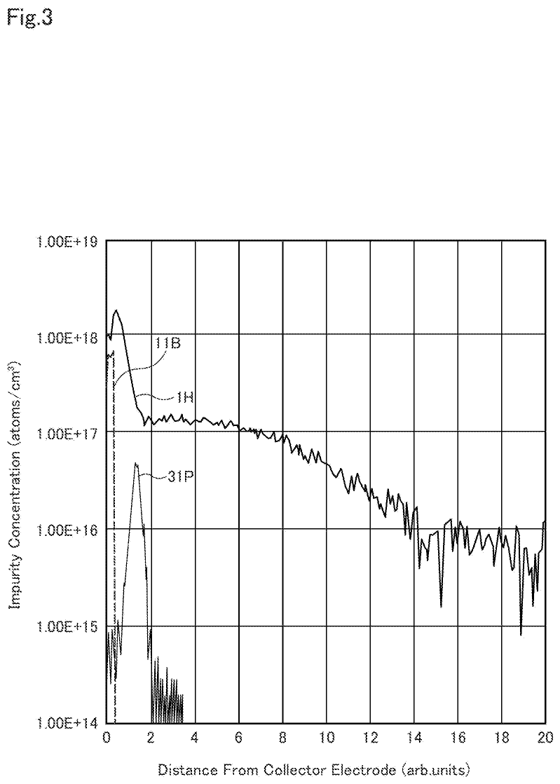

FIG. 3 is the graph showing the impurity concentration in the semiconductor device 100 of the present embodiment. The horizontal axis of FIG. 3 indicates the distance from the collector electrode 4 in the direction parallel to the Z-direction. The longer the distance from the collector electrode 4, the closer to the second surface 2b.

FIG. 3 shows the impurity concentration of boron (¹¹B), phosphorus (³¹P), and hydrogen (¹H).

FIG. 3 indicates that the second buffer layer 12 has the hydrogen concentration of 5×10¹⁷ atoms/cm³ or more. In the exemplary embodiment shown in FIG. 3, the second buffer layer 12 is provided over the collector layer 6 and the first buffer layer 8.

The hydrogen concentration increases to around 2×10¹⁸ atoms/cm³ as the distance from the collector electrode 4 increases. The distance between the region where the hydrogen concentration is increased to around 2×10¹⁸ atoms/cm³ and the collector electrode 4 (or the first surface 2a) corresponds to the projected range Rp of protons. Further, as the distance from the collector electrode 4 increases, the hydrogen concentration decreases relatively rapidly to around 2×10¹⁷ atoms/cm³. Thereafter, the hydrogen concentration decreases relatively slowly with increasing distance from the collector electrode 4.

The change in the hydrogen concentration from the collector electrode 4 is not limited to that shown in FIG. 3.

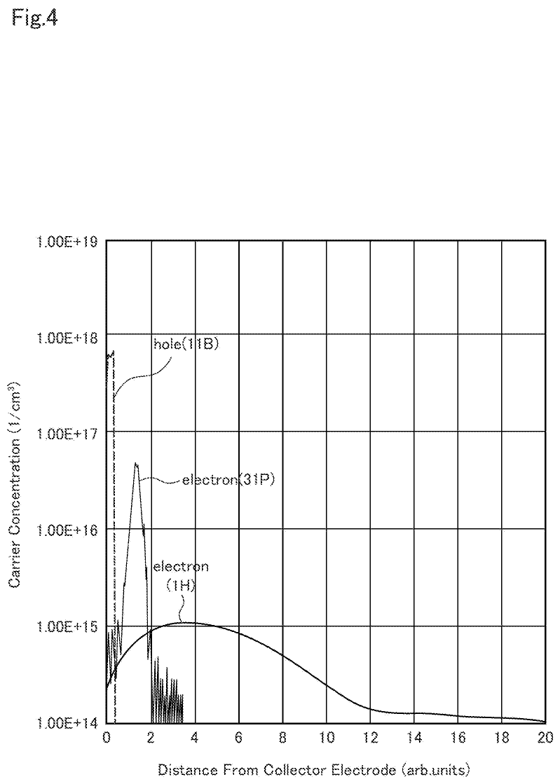

FIG. 4 is the graph showing the carrier concentration in the semiconductor device 100 of the present embodiment. The horizontal axis of FIG. 4 indicates the distance from the collector electrode 4 in the direction parallel to the Z-direction. In FIG. 4, the carrier concentration of holes from boron (¹¹B), the carrier concentration of electrons from phosphorus (³¹P), and the carrier concentration of electrons from hydrogen (¹H) “N⁻” are shown.

The dependence of the carrier concentration of the holes from boron on the distance from the collector electrode 4 is approximately the same as the dependence of the impurity concentration of boron on the distance from the collector electrode 4.

The dependence of the carrier concentration of electrons from phosphorus on the distance from the collector electrode 4 is approximately the same as the dependence of the impurity concentration of phosphorus on the distance from the collector electrode 4.

The activation rate of hydrogen is lower than the activation rate of boron and the activation rate of phosphorus. The activation rate of hydrogen is about 1%. Therefore, the carrier concentration (N⁻) of electrons from hydrogen is lower than the hydrogen concentration.

In addition, the hydrogen concentration increases sharply to around 2×10¹⁸ atoms/cm³ in the distance corresponding to the projected range of protons. However, there is no sharp increase in the carrier concentration of electrons from hydrogen as seen in the hydrogen concentration at a distance corresponding to the projected range of protons.

The carrier concentration (N⁻) of the electrons from hydrogen increases to around 1×10¹⁵/cm³ with increasing distance from the collector electrode. The carrier concentration of electrons from hydrogen decreases slowly as the distance from the collector electrode increases further.

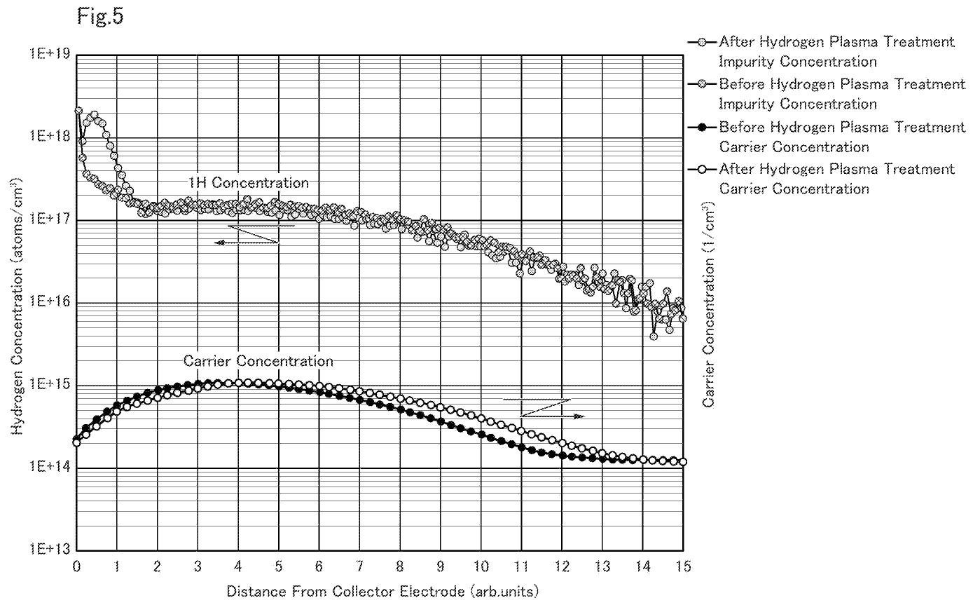

FIG. 5 is the graph showing the hydrogen concentration and the n-type carrier concentration before and after the hydrogen plasma treatment in the semiconductor device 100 of the present embodiment. The n-type carrier concentration is approximately the same before and after the hydrogen plasma treatment. On the other hand, after the hydrogen plasma treatment, the hydrogen concentration increases sharply up to around 2×10¹⁸ atoms/cm³ at a distance corresponding to the projected range of protons. In other words, the semiconductor device 100 of the present embodiment includes the second buffer layer 12 having a high concentration of hydrogen having a low donor contribution rate in the vicinity of a distance corresponding to the projected range of protons. Here, the hydrogen concentration in the second buffer layer 12 is preferably 500 times or more higher than the n-type carrier concentration (the first conductivity type carrier concentration) of the second buffer layer 12.

The impurity concentration in the semiconductor device 100 can be measured by, for example, Secondary Ion Mass Spectroscopy (SIMS).

The carrier density in the semiconductor device 100 can be measured by, for example, Spreading Resistance Analysis (SRA).

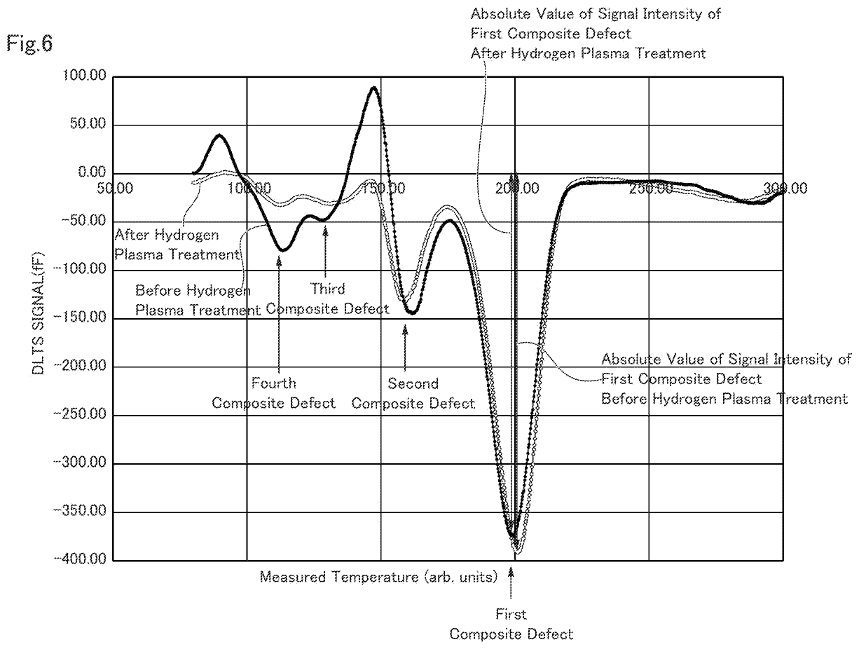

FIG. 6 is the DLTS (Deep Level Transient Spectroscopy) spectrum waveform before and after the hydrogen plasma treatment in the semiconductor device 100 of the present embodiment. Peaks by the first composite defect, the second composite defect, the third composite defect, and the fourth composite defect have been observed.

Here, the measured temperature of the second composite defect measured by deep level transient spectroscopy is lower than the measured temperature of the first composite defect measured by deep level transient spectroscopy. The measured temperature of the third composite defect measured by deep level transient spectroscopy is lower than the measured temperature of the second composite defect measured by deep level transient spectroscopy. The measured temperature of the fourth composite defect measured by deep level transient spectroscopy is lower than the measured temperature of third composite defect measured by deep level transient spectroscopy. Further, the lower the measured temperature, the shallower the trap level of the crystal defect in the semiconductor substrate 2. Therefore, the trap level of the second composite defect is shallower than the trap level of the first composite defect, the trap level of the third composite defect is shallower than the trap level of the second composite defect, and the trap level of the fourth composite defect is shallower than the trap level of the third composite defect.

The absolute value of the signal intensity of the first composite defect before and after the hydrogen plasma treatment are shown in FIG. 6.

The first composite defect is a defect including O (oxygen) and C (carbon). The second composite defect is a defect including O (oxygen), C (carbon), and H (hydrogen). The third composite defect includes any of O, C, H, Si, and V (vacancies), and is a defect that differs from the first composite defect and the second composite defect. The fourth composite defect includes any of O, C, H, Si, and V (vacancies), and is a defect that differs from the first composite defect, the second composite defect, and the third composite defect.

The absolute value of the signal intensity of the third composite defect and the absolute value of the signal intensity of the fourth composite defect after the hydrogen plasma treatment are smaller than the absolute value of the signal intensity of the third composite defect and the absolute value of the signal intensity of the fourth composite defect before the hydrogen plasma treatment. This indicates that the amount of the third composite defect and the amount of the fourth composite defect are reduced by the hydrogen plasma treatment.

Here, it is preferable that the absolute value of the signal intensity of the first composite defect measured by deep level transient spectroscopy is four times or more higher than the sum of the absolute value of the signal intensity of the third composite defect measured by deep level transient spectroscopy and the absolute value of the signal intensity of the fourth composite defect measured by deep level transient spectroscopy.

Further, it is preferable that the absolute value of the signal intensity of the second composite defect measured by the deep level transient spectroscopy is three times or more higher than the sum of the absolute value of the signal intensity of the third composite defect measured by deep level transient spectroscopy and the absolute value of the signal intensity of the fourth composite defect measured by deep level transient spectroscopy.

Carrier lifetime was measured by the μ-PCD (Microwave Photo Conductivity Decay method). The carrier lifetime before the hydrogen plasma treatment was 239.1 μsec, whereas the carrier lifetime after the hydrogen plasma treatment increased to 338.1 μsec. It is considered that the carrier lifetime increased because the amount of the third composite defect and the amount of the fourth composite defect were reduced by the hydrogen plasma treatment.

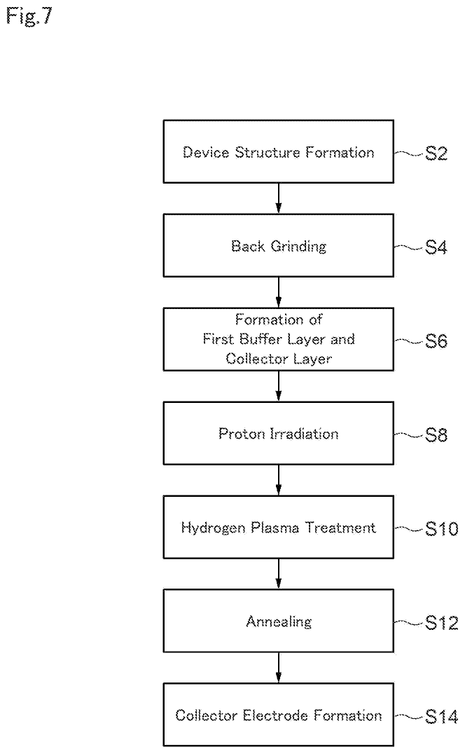

FIG. 7 is the flow chart showing the process for manufacturing the semiconductor device according to the present embodiment.

A method of manufacturing the semiconductor device according to the present embodiment includes forming a first semiconductor layer of a first conductivity type by implanting first conductivity type impurities on a first surface of a semiconductor substrate, the semiconductor substrate including the first surface and a second surface opposite to the first surface, and the second surface facing the first surface; irradiating protons on the first surface; performing hydrogen plasma treatment on the first surface; annealing the semiconductor substrate; and forming a third semiconductor layer provided in the first semiconductor layer, and the third semiconductor layer having a hydrogen concentration of 5×10¹⁷ atoms/cm³ or more.

First, the semiconductor substrate 2 is prepared. Here, the semiconductor substrate 2 is, for example, an n-type silicon substrate including phosphorus. Next, an IGBT device is formed on the second surface 2b of the semiconductor substrate 2. That is, the base region 50, the emitter region 44, the contact region 46, the trench 30, the gate electrode 42, the interlayer insulating film 48, and the emitter 20 are formed on the second surface 2b of the semiconductor substrate 2 (S2).

Next, the first surface 2a of the semiconductor substrate 2 is ground to form the semiconductor substrate 2 to a desired thickness (S4).

Next, phosphorus, for example, is implanted on the first surface 2a of the ground semiconductor substrate 2 by, for example, an ion implantation method to form the n-type first buffer layer 8 on the first surface 2a side. Further, for example, boron is implanted into a position shallower than the first buffer layer 8 (the first surface 2a side) from the ground first surface 2a of the ground semiconductor substrate 2 by, for example, an ion implantation method to form the collector layer 6 below the first buffer layer 8 (S6). The semiconductor substrate 2 between the first buffer layer 8 and the base region 50 of IGBT is used as the drift layer 10.

Next, protons are irradiated on the first surface 2a of the ground semiconductor substrate 2 (S8). Here, the irradiation of the protons is performed by, for example, a method using a cyclotron accelerator. The accelerating energy of the protons is, for example, of the order of 4 MeV. The injected amounts of protons are, for example, 1.5×10¹⁴/cm². The proton irradiation may be performed by an ion implantation method.

Next, the first surface 2a of the ground semiconductor substrate 2 is subjected to the hydrogen plasma treatment (S10). Here, the hydrogen plasma treatment is performed in an atmosphere of, for example, 400° C. for 5 minutes.

Next, the semiconductor substrate 2 subjected to the hydrogen plasma treatment described above is annealed in, for example, a N₂ gas (nitrogen gas) (S12). Here, the annealing is performed at 400° C. for 120 minutes, for example.

As a result, the second buffer layer 12 is formed.

Next, the collector electrode 4 is formed on the first surface 2a of the ground semiconductor substrate (S14). Then, the semiconductor device 100 according to the present embodiment is obtained.

Next, the operation and effect of the semiconductor device 100 of the present embodiment will be described.

During the switching process of IGBT, V ce sometimes vibrates and oscillates. Therefore, it has been desired to suppress such oscillation. Here, it is considered that such oscillations occur because, for example, when the depletion layer spreads from the base region 50 to the drift layer 10 when IGBT is turned off, the accumulated carriers are reduced.

Therefore, the device of the present embodiment includes a first semiconductor layer of a first conductivity type, and the first semiconductor layer including first conductivity type impurities; a second semiconductor layer of the first conductivity type provided on the first semiconductor layer, and the second semiconductor layer including lower first conductivity type impurities than the first semiconductor layer; and a third semiconductor layer provided in the first semiconductor layer, and the third semiconductor layer including a hydrogen concentration of 5×10¹⁷ atoms/cm³ or more.

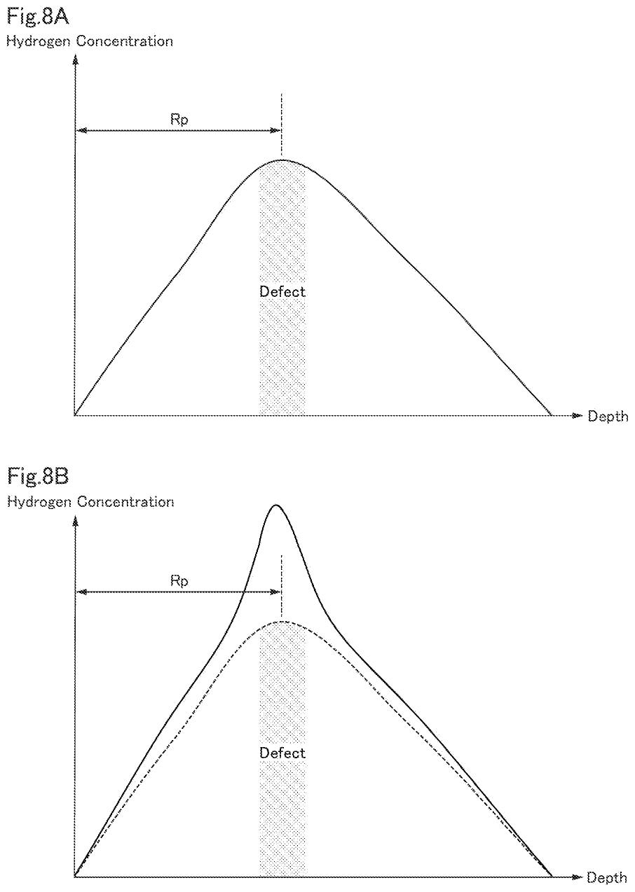

FIG. 8A-B are the diagrams schematically showing the hydrogen concentration in the depth direction in the semiconductor device of the present embodiment.

FIG. 8A is the diagram schematically showing the hydrogen concentration in the depth direction in the semiconductor device as a comparative embodiment of the present embodiment. Here, in the semiconductor device according to the comparative embodiment, after the first surface 2a of the semiconductor substrate 2 is irradiated with protons, it is annealed without performing the hydrogen plasma treatment.

By irradiating protons, it is possible to form n-type semiconductor layers that are closer (deeper in depth) to the second surface 2b than when using phosphorus, for example. Thus, the number of carriers can be increased. However, at a depth corresponding to the projected range of protons, a large number of crystal defects are formed. The crystal defects cause a problem that the carrier lifetime is shortened. Further, even if annealing is performed to reduce the crystal defects, there is a problem that the crystal defects remain.

FIG. 8B is the diagram schematically showing the hydrogen concentration in the depth direction in the semiconductor device 100 according to the present embodiment. Here, in the semiconductor device 100 of the present embodiment, after the first surface 2a of the semiconductor substrate 2 is irradiated with protons, the hydrogen plasma treatment is performed, and then annealing is performed.

In the semiconductor device 100 of the present embodiment, hydrogen is trapped in the vicinity of the depth corresponding to the projected range of protons by the hydrogen plasma treatment and subsequent annealing, and the second buffer layer 12 is formed. The crystal defects formed by the proton irradiation are considered to be hydrogen-terminated by hydrogen. The second buffer layer 12 has the hydrogen concentration of 5×10¹⁷ atoms/cm³ or more and is very high. Therefore, the hydrogen termination is sufficiently performed. As a result, the carrier trap is greatly reduced, and the carrier lifetime can be increased.

Therefore, the oscillation of V_{ce} can be suppressed.

On the other hand, as explained using FIG. 5, hydrogen-terminated hydrogen is considered to have a low donor contribution ratio and not to contribute much to the n-type carrier concentration. The hydrogen concentration in the second buffer layer 12 is preferably 500 times or more higher than the n-type carrier concentration in the second buffer layer 12. This is because, in this case, since the hydrogen concentration is sufficiently high, the crystal defects are satisfactorily terminated with hydrogen, and the carrier lifetime is considered to be increased.

Further, it is considered that the amount of the third composite defect and the amount of the fourth composite defect are reduced due to the hydrogen termination of the crystal defects.

It is preferable that the carrier lifetime is sufficiently increased by decreasing the amount of the third composite defect and the amount of the fourth composite defect so that the absolute value of the signal intensity of the first composite defect measured by deep level transient spectroscopy is four times or more higher than the sum of the absolute value of the signal intensity of the third composite defect measured by deep level transient spectroscopy and the absolute value of the signal intensity of the fourth composite defect measured by deep level transient spectroscopy.

It is preferable that the carrier lifetime is sufficiently increased by decreasing the amount of the third composite defect and the amount of the fourth composite defect so that the absolute value of the signal intensity of the second composite defect measured by deep level transient spectroscopy is three times or more higher than the sum of the absolute value of the signal intensity of the third composite defect measured by deep level transient spectroscopy and the absolute value of the signal intensity of the fourth composite defect measured by deep level transient spectroscopy.

According to the semiconductor device of the present embodiment, it is possible to provide a semiconductor device with an increased carrier lifetime.

### Second Embodiment

In the semiconductor device of the present embodiment, the third electrode of the semiconductor device of the first embodiment is replaced with the fifth electrode. In the semiconductor device of the present embodiment, the fourth semiconductor layer of the semiconductor device of the first embodiment is replaced with the sixth semiconductor layer. In the semiconductor device of the present embodiment, the second electrode of the first embodiment is replaced with the fourth electrode. Further, the semiconductor device of the present embodiment does not include the first semiconductor region, the second semiconductor region, the first electrode, the second electrode, the first insulating film, and the second the insulating film of the semiconductor device of the first embodiment. The semiconductor device of the present embodiment includes the fifth semiconductor layer. Here, description of the same content as that of the first embodiment is omitted.

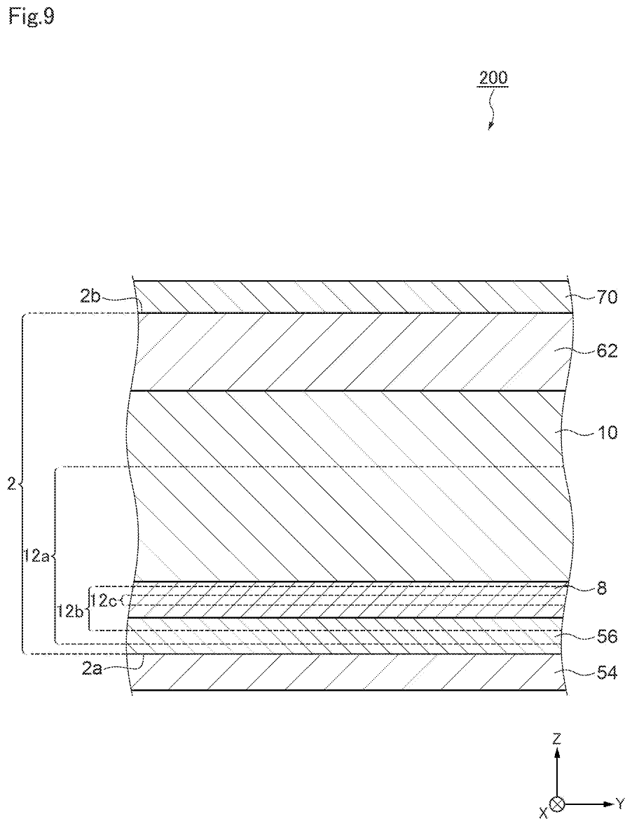

FIG. 9 is the schematic cross-sectional view of a semiconductor device 200 according to the present embodiment. The device 200 of the present embodiment is a PIN type diode.

The device 200 includes the semiconductor substrate 2, a cathode electrode 54 and an anode electrode 70. The semiconductor substrate includes a cathode layer 56, a first buffer layer 8, the drift layer 10, the second buffer layer 12 and an anode layer 62.

The anode layer 62 is an example of the fifth semiconductor layer. The anode electrode 70 is an example of the fourth electrode. The cathode layer 56 is an example of the sixth semiconductor layer. The cathode electrode 54 is an example of the fifth electrode.

The anode layer 62 is provided in the semiconductor substrate 2. The anode layer 62 is provided on the drift layer 10. The anode layer 62 includes, for example, a p-type semiconductor material. The anode layer 62 includes p-type impurities, for example, 1×10¹⁶ atoms/cm³ or more and 1×10²¹ atoms/cm³ or less.

The anode electrode 70 is provided on the anode layer 62. The anode electrode 70 is electrically connected to the anode layer 62.

The cathode layer 56 is provided in the semiconductor substrate 2. The cathode layer 56 is provided, for example, below the first buffer layer 8 and parallel to XY plane. The cathode layer 56 includes, for example, an n-type semiconductor material. The cathode layer 56 includes n-type impurities, for example, 1×10¹⁹ atoms/cm³ or more and 1×10²¹ atoms/cm³ or less.

The cathode electrode 54 is provided below the semiconductor substrate 2. The cathode electrode 54 is provided below the cathode layer 56. The cathode electrode 54 is electrically connected to the cathode layer 56.

The position at which the second buffer layer 12 is provided depends on the above-described process of proton irradiation on the first surface 2a, subsequent hydrogen plasma treatment on the first surface 2a, and subsequent annealing of the semiconductor substrate 2. For example, the second buffer layer 12 may be provided in the first buffer layer 8 as illustrated as the second buffer layer 12c in FIG. 9. In addition, the second buffer layer 12 may be provided over the cathode layer 56 and the first buffer layer 8 as illustrated as the second buffer layer 12b in FIG. 9. In addition, the second buffer layer 12 may be provided over the cathode layer 56, the first buffer layer 8, and the drift layer 10 as illustrated as the second buffer layer 12a in FIG. 9. For example, the second buffer layer 12 may be provided in the cathode layer 56. For example, the second buffer layers 12 may be provided in the drift layer 10. Further, for example, the second buffer layer 12 may be provided over the first buffer layer 8 and the drift layer 10. When the second buffer layer 12 is provided in the first buffer layer 8, the second buffer layer 12 is provided above (provided on) the cathode layer 56.

The anode electrode 70 and the cathode electrode 54 each include a conductive material such as Al (aluminium).

The semiconductor device of the present embodiment can also provide a semiconductor device with an increased carrier lifetime.

While certain embodiments have been described, these embodiments have been presented by way of example only, and are not intended to limit the scope of the inventions. Indeed, Semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer of a first conductivity type, and the first semiconductor layer including first conductivity type impurities;
a second semiconductor layer of the first conductivity type provided on the first semiconductor layer, and the second semiconductor layer including lower first conductivity type impurities than the first semiconductor layer; and
a third semiconductor layer provided in the first semiconductor layer, and the third semiconductor layer including a hydrogen concentration of 5×10¹⁷ atoms/cm³ or more.

2. The semiconductor device according to claim 1, wherein the hydrogen concentration in the third semiconductor layer is 500 times or more higher than a concentration of a first conductivity type carrier in the third semiconductor layer.

3. The semiconductor device according to claim 1, wherein the third semiconductor layer includes
a first composite defect,
a second composite defect having a lower measured temperature measured by deep level transient spectroscopy than a measured temperature of the first composite defect measured by deep level transient spectroscopy,
a third composite defect having a lower measured temperature measured by deep level transient spectroscopy than the measured temperature of the second composite defect measured by deep level transient spectroscopy, and
a fourth composite defect having a lower measured temperature by deep level transient spectroscopy than the measured temperature of the third composite defect measured by deep level transient spectroscopy,
wherein an absolute value of a signal intensity of the first composite defect measured by deep level transient spectroscopy is four times or more higher than a sum of an absolute value of a signal intensity of the third composite defect measured by deep level transient spectroscopy and an absolute value of a signal intensity of the fourth composite defect measured by deep level transient spectroscopy.

4. The semiconductor device according to claim 1, wherein the third semiconductor layer includes
a first composite defect,
a second composite defect having a lower measured temperature measured by deep level transient spectroscopy than a measured temperature of the first composite defect measured by deep level transient spectroscopy,
a third composite defect having a lower measured temperature measured by deep level transient spectroscopy than the measured temperature of the second composite defect measured by deep level transient spectroscopy, and
a fourth composite defect having a lower measured temperature by deep level transient spectroscopy than the measured temperature of the third composite defect measured by deep level transient spectroscopy,
wherein an absolute value of a signal intensity of the second composite defect measured by deep level transient spectroscopy is three times or more higher than a sum of an absolute value of a signal intensity of the third composite defect measured by deep level transient spectroscopy and an absolute value of a signal intensity of the fourth composite defect measured by deep level transient spectroscopy.

5. The semiconductor device according to claim 1, further comprising:
a first semiconductor region of a second conductivity type provided on the second semiconductor layer;
a second semiconductor region of the first conductivity type provided on the first semiconductor region;
a first electrode provided in a trench, the trench reaching the second semiconductor layer from above the second semiconductor region, and the first electrode facing the first semiconductor region via a first insulating film;
a second insulating film provided on the first electrode;
a second electrode provided on the second semiconductor region and the second insulating film;
a fourth semiconductor layer provided below the first semiconductor layer; and
a third electrode provided below the fourth semiconductor layer, and the third electrode being electrically connected to the fourth semiconductor layer.

6. The semiconductor device according to claim 5, wherein the third semiconductor layer is provided over the first semiconductor layer and the fourth semiconductor layer.

7. The semiconductor device according to claim 5, wherein the third semiconductor layer is provided over the second semiconductor layer, the first semiconductor layer and the fourth semiconductor layer.

8. The semiconductor device according to claim 1, further comprising:
a first semiconductor region of a second conductivity type provided on the second semiconductor layer;
a second semiconductor region of the first conductivity type provided in the first semiconductor region;
a first electrode provided above the first semiconductor region;
a first insulating film provided between the first semiconductor region and the first electrode;
a second insulating film provided on the first electrode;
a second electrode provided on the second semiconductor region and the second insulating film;
a fourth semiconductor layer provided below the first semiconductor layer; and
a third electrode provided below the fourth semiconductor layer, and the third electrode being electrically connected to the fourth semiconductor layer.

9. The semiconductor device according to claim 8, wherein the third semiconductor layer is provided over the first semiconductor layer and the fourth semiconductor layer.

10. The semiconductor device according to claim 8, wherein the third semiconductor layer is provided over the second semiconductor layer, the first semiconductor layer and the fourth semiconductor layer.

11. The semiconductor device according to claim 1, further comprising:
a fifth semiconductor layer of a second conductivity type provided on the second semiconductor layer;
a fourth electrode provided on the fifth semiconductor layer, and the fourth electrode being electrically connected to the fifth semiconductor layer;
a sixth semiconductor layer provided below the first semiconductor layer; and
a fifth electrode provided below the sixth semiconductor layer, and the fifth electrode being electrically connected to the sixth semiconductor layer.

12. The semiconductor device according to claim 11, wherein the third semiconductor layer is provided over the first semiconductor layer and the sixth semiconductor layer.

13. The semiconductor device according to claim 11, wherein the third semiconductor layer is provided over the second semiconductor layer, the first semiconductor layer and the sixth semiconductor layer.

14. A method of manufacturing a semiconductor device comprising:
forming a first semiconductor layer of a first conductivity type by implanting first conductivity type impurities on a first surface of a semiconductor substrate, the semiconductor substrate including the first surface and a second surface opposite to the first surface, and the second surface facing the first surface;
irradiating protons on the first surface;
performing hydrogen plasma treatment on the first surface;
annealing the semiconductor substrate; and
forming a third semiconductor layer provided in the first semiconductor layer, and the third semiconductor layer having a hydrogen concentration of 5×10¹⁷ atoms/cm³ or more.

15. The method according to claim 14, wherein the hydrogen concentration in the third semiconductor layer is 500 times or more higher than a concentration of a first conductivity type carrier in the third semiconductor layer.

16. The method according to claim 14, wherein the third semiconductor layer includes
a first composite defect,
a second composite defect having a lower measured temperature measured by deep level transient spectroscopy than a measured temperature of the first composite defect measured by deep level transient spectroscopy,
a third composite defect having a lower measured temperature measured by deep level transient spectroscopy than the measured temperature of the second composite defect measured by deep level transient spectroscopy, and
a fourth composite defect having a lower measured temperature by deep level transient spectroscopy than the measured temperature of the third composite defect measured by deep level transient spectroscopy,
wherein an absolute value of a signal intensity of the first composite defect measured by deep level transient spectroscopy is four times or more higher than a sum of an absolute value of a signal intensity of the third composite defect measured by deep level transient spectroscopy and an absolute value of a signal intensity of the fourth composite defect measured by deep level transient spectroscopy.

17. The method according to claim 14, wherein the third semiconductor layer includes
a first composite defect,
a second composite defect having a lower measured temperature measured by deep level transient spectroscopy than a measured temperature of the first composite defect measured by deep level transient spectroscopy,
a third composite defect having a lower measured temperature measured by deep level transient spectroscopy than the measured temperature of the second composite defect measured by deep level transient spectroscopy, and
a fourth composite defect having a lower measured temperature by deep level transient spectroscopy than the measured temperature of the third composite defect measured by deep level transient spectroscopy,
wherein an absolute value of a signal intensity of the second composite defect measured by deep level transient spectroscopy is three times or more higher than a sum of an absolute value of a signal intensity of the third composite defect measured by deep level transient spectroscopy and an absolute value of a signal intensity of the fourth composite defect measured by deep level transient spectroscopy.
